(19) United States
(12) Patent Application Publication
(10) Pub. No.: US 2025/0107140 A1
(43) Pub. Date: Mar. 27, 2025

(54) SEMICONDUCTOR DEVICE AND MANUFACTURING METHOD THEREOF

(71) Applicant: Hon Young Semiconductor Corporation, Hsinchu City (TW)

(72) Inventors: Jing-Neng YAO, Hsinchu City (TW); Yan-Ru CHEN, Hsinchu City (TW); Ying-Tso CHEN, Hsinchu City (TW)

(21) Appl. No.: 18/432,066

(22) Filed: Feb. 5, 2024

(30) Foreign Application Priority Data
Sep. 26, 2023 (TW) 112136909

(51) Int. Cl. H01L 29/78; H01L 21/266; H01L 21/308; H01L 29/06; H01L 29/66

(52) U.S. Cl. CPC H10D 30/668; H01L 21/266; H01L 21/3086; H10D 30/0297; H10D 62/106

(57) ABSTRACT

A manufacturing method of a semiconductor device includes providing a substrate, forming a first trench in the substrate, in which a top of the first trench is greater than a bottom of the first trench, forming a well region and a source region at a side of the first trench, in which the source region is on the well region, forming a hard mask stack lining a surface of the substrate, forming a second trench in the hard mask stack, in which the bottom of the second trench is over the corner of the first trench, performing an implantation process to form a shielding doped region at a region of the substrate nearing the corner of the first trench, removing the hard mask stack, forming a gate dielectric layer lining the surface of the substrate, and forming a gate in the first trench.

### CROSS-REFERENCE TO RELATED APPLICATION

This application claims priority to Taiwan Application Serial Number 112136909, filed Sep. 26, 2023, which is herein incorporated by reference in its entirety.

### BACKGROUND

### Field of Disclosure

Some embodiments of the present disclosure relate to a semiconductor device and a manufacturing method thereof.

### Description of Related Art

The trench gate is one of common gate forms in semiconductor devices. Compared with a planar gate, the trench gate can reduce a distance between gates to increase a quantity of gates per unit area. The bottom of the trench gate is prone to generate a strong electric field, which increases leakage current and even damages an insulation layer. In general, a shielding doped region is formed at the bottom of the trench gate to eliminate the strong electric field, which reduces the leakage current of the semiconductor device.

### SUMMARY

Some embodiments of the present disclosure provide a method of manufacturing a semiconductor device, including: providing a substrate; forming a first trench in the substrate, in which a top width of the first trench is greater than a bottom width of the first trench; forming a well region and a source region at a side of the first trench, in which the source region is on the well region; forming a hard mask stack lining a surface of the substrate; defining a second trench by a photomask, in which the bottom of the second trench is over a corner of the first trench; performing an ion implantation process to form a shielding doped region at the corner of the first trench; removing the hard mask stack; forming a gate dielectric layer lining the surface of the substrate, in which the gate dielectric layer covers the shielding doped region; and forming a gate in the first trench.

Some embodiments of the present disclosure provide a semiconductor device, including a substrate, a gate dielectric layer, a shielding doped region, a well region, and a source region. A gate extends downward from a surface of the substrate, and a top width of the gate is greater than a bottom width of the gate. The gate dielectric layer is located between the substrate and the gate. The shielding doped region is located in the substrate and below a corner of the gate and the gate dielectric layer. The well region is located in the substrate and on a side of the gate dielectric layer. The source region is located in the substrate and on a side of the gate dielectric layer, and the source region is located on the well region.

Some embodiments of the present disclosure provide a semiconductor device, including a substrate, a gate dielectric layer, a shielding doped region, a well region, and a source region. A gate extends downward from a surface of the substrate, and the gate has a stepped side wall. The gate dielectric layer is located between the substrate and the gate. The shielding doped region is located in the substrate and below a corner of the gate and the gate dielectric layer. The well region is located in the substrate and on a side of the gate dielectric layer. The source region is located in the substrate and on a side of the gate dielectric layer, and the source region is located on the well region.

Some embodiments of the present disclosure can be applied to form a gate that is wide at the top and narrow at the bottom. Therefore, a shielding doped region formed at the corner of the gate is not easy to block a path of an electron flow, thereby reducing the resistance of the semiconductor device.

### BRIEF DESCRIPTION OF THE DRAWINGS

FIGS. 1-5 illustrate cross-sectional views of a process of a semiconductor device according to some embodiments of the present disclosure;

FIG. 6 illustrates a cross-sectional view of another embodiment of forming a first trench according to the present disclosure; and

FIGS. 7-12 illustrate cross-sectional views of another embodiment of forming a first trench according to the present disclosure.

### DETAILED DESCRIPTION

Some embodiments of the present disclosure can be applied to form a gate that is wide at the top and narrow at the bottom. Therefore, a shielding doped region formed at the corner of the gate is not easy to block a path of an electron flow, thereby reducing the resistance of the semiconductor device.

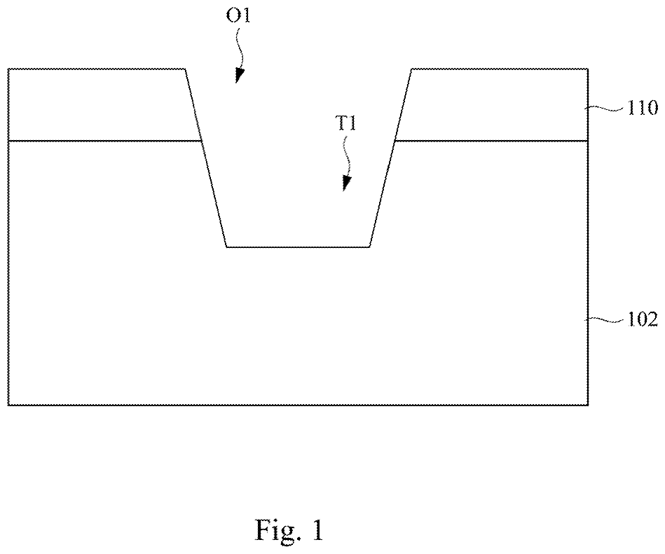

FIGS. 1-5 illustrate cross-sectional views of a process of a semiconductor device 100 according to some embodiments of the present disclosure. Referring to FIG. 1, a substrate 102 is provided. The substrate 102 may be made of silicon carbide, silicon, gallium nitride, gallium arsenide, and indium phosphide. In some embodiments, the substrate 102 is N-type, and may include an N-type dopant, such as arsenic, phosphorus and nitrogen. The substrate 102 may be a lightly doped substrate.

A hard mask layer 110 is formed on the substrate 102. The hard mask layer 110 may be made of silicon dioxide, silicon nitride, or a combination thereof. A total thickness of the hard mask layer 110 is 1-5 μm, such as 3 μm.

Then the hard mask layer 110 is patterned. The hard mask layer 110 is patterned in the following way: forming a patterned photoresist layer on the hard mask layer 110. In some embodiments, the patterned photoresist layer is formed using a spin-coating process. In some embodiments, a total thickness of the patterned photoresist layer is greater than 3 μm. In some embodiments, the total thickness of the patterned photoresist layer is greater than a total thickness of the hard mask layer 110 by 1-3 μm. Then the patterned photoresist layer is exposed by a photomask, the patterned photoresist layer is developed to remove an exposed region and leave an unexposed region. Then a first etching process is performed on the hard mask layer 110 via the patterned photoresist layer, to form an inverted trapezoidal opening O1 in the hard mask layer 110. Performing the first etching process includes adjusting at least one of a plurality of etching parameters. Etching parameters include etching gas concentration and etching energy. For example, the etching parameters may be adjusted with a change in an etching depth of the hard mask layer 110, such that an etching gas in the etching process has different etching capabilities for the hard mask layer 110 at different etching depths, thereby forming the inverted trapezoidal opening O1. In some embodiments, when the hard mask layer 110 is etched deeper, the etching gas concentration may be smaller or the etching energy may be smaller. The patterned photoresist layer may be removed after the hard mask layer 110 is patterned.

A second etching process is then performed on the substrate 102 via the hard mask layer 110, to form a first trench T1 in the substrate 102. A top width of the first trench T1 is greater than a bottom width of the first trench T1. During the second etching process, the etching parameters of the second etching process remain consistent. The etching parameters include etching gas concentration and etching energy. In this way, the etching gas naturally etches the first trench T1 in the substrate 102. In some embodiments, the first trench T1 has an inclined side wall like a side wall of the inverted trapezoidal opening O1 of the hard mask layer 110. The hard mask layer 110 may be removed after the first trench T1 is formed.

In some embodiments, after the hard mask layer 110 is removed, a sacrificial oxide layer is formed on the substrate 102 by using a thermal oxidation process. The sacrificial oxide layer may be used for repairing a surface of the substrate 102 damaged when etching the substrate 102, such that the surface of the substrate 102 may become smoother. The sacrificial oxide layer is then removed using a wet etching process.

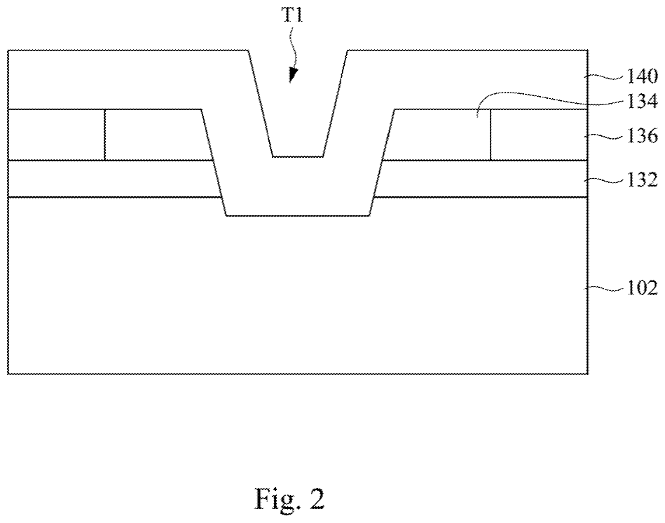

Referring to FIG. 2, a well region 132, a source region 134 and a base region 136 are formed on a side of the first trench T1, the source region 134 is on the well region 132, and the base region 136 is on the well region 132 and adjacent to the source region 134. The bottom of the well region 132 is higher than the bottom of the first trench T1. The well region 132 and the base region 136 may have a second semiconductor type, and the source region 134 may have a first semiconductor type. In some embodiments, the well region 132 and the base region 136 may be P-type and include a P-type dopant, such as boron, gallium and aluminum. The well region 132 may be a lightly doped region, and the base region 136 may be a heavily doped region. The source region 134 may be N-type and includes an N-type dopant, such as arsenic, phosphorus and nitrogen. The source region 134 may be a heavily doped region. The well region 132, the source region 134 and the base region 136 can be formed in any suitable sequence. For example, the well region 132 is first formed in the substrate 102, then the source region 134 is formed, and finally the base region 136 is formed.

A hard mask stack 140 is then formed lining a surface of the substrate 102. The hard mask stack 140 includes a first hard mask sublayer, a second hard mask sublayer and a third hard mask sublayer from bottom to top. The first hard mask sublayer and the third hard mask sublayer are made of a first material, and the second hard mask sublayer is made of a second material different from the first material. In some embodiments, the first hard mask sublayer is made of silicon dioxide and has a thickness of 50 nm, the second hard mask sublayer is made of silicon nitride and has a thickness of 50 nm, and the third hard mask sublayer is made of silicon dioxide and has a thickness of 1-2 μm.

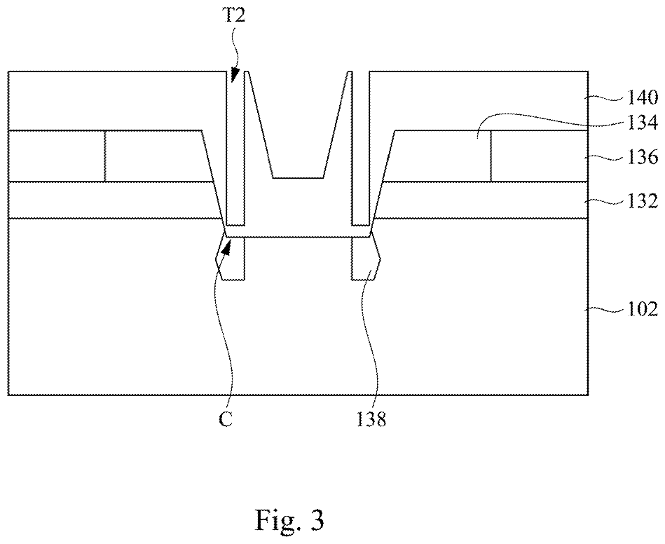

Referring to FIG. 3, a second trench T2 is formed in the hard mask stack 140, and the bottom of the second trench T2 is over a corner C of the first trench T1. Specifically, a photoresist layer is formed on the hard mask stack 140, then the photoresist layer is exposed by a photomask, and the photoresist layer is developed, to leave an unexposed region of the photoresist layer.

The photoresist layer is then used as an etching mask to form the second trench T2 in the hard mask stack 140. In some embodiments, the bottom of the second trench T2 is on an upper surface of the first hard mask sublayer, that is, the second trench T2 penetrates through the second hard mask sublayer and the third hard mask sublayer, but does not penetrate through the first hard mask sublayer. In some embodiments, the bottom of the second trench T2 may also be on an upper surface of the second hard mask sublayer, that is, the second trench T2 penetrates through the third hard mask sublayer, but does not penetrate through the first hard mask sublayer and the second hard mask sublayer. In this way, the surface of the substrate 102 is not damaged when the second trench T2 is formed and the ion implantation process is performed subsequently. The photoresist layer may be removed after the second trench T2 is formed.

The ion implantation process is then performed, the hard mask stack 140 is used as a mask to implant ions from the second trench T2 to a region of the substrate 102 nearing the corner C of the first trench T1, to form a shielding doped region 138. The shielding doped region 138 may be P-type and includes a P-type dopant, such as boron, gallium and aluminum. The shielding doped region 138 may be a heavily doped region. In some embodiments, the shielding doped region 138 is lower than the well region 132. The shielding doped region 138 may be used for increasing a breakdown voltage and alleviating the problem of gate leakage in the operation of the semiconductor device 100.

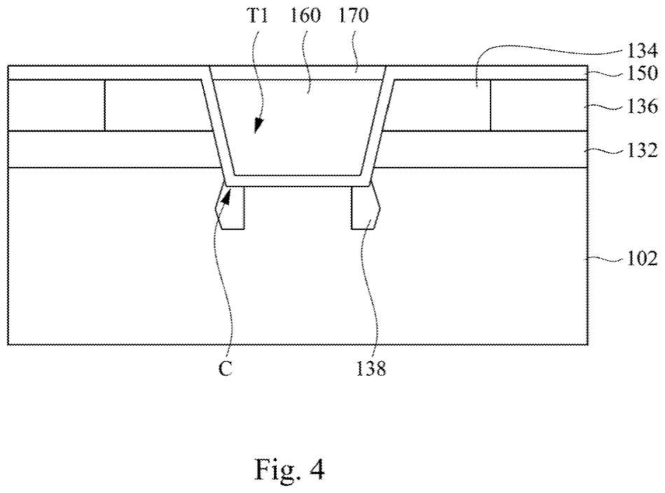

Then, referring to FIG. 4, the hard mask stack 140 is removed, and an annealing process is performed to activate doped regions, such as the well region 132, the source region 134, the base region 136, and the shielding doped region 138. The annealing process may be performed at a temperature in a range from 1500 degrees Celsius to 1800 degrees Celsius. In some embodiments, before the annealing process, a graphite protective layer is formed on the substrate 102 to prevent atoms of the substrate 102 from desorbing at high temperature to form a rough surface. The graphite protective layer may be prepared by baking a photoresist material. The graphite protective layer is removed after the annealing process.

Referring to FIG. 4, a gate dielectric layer 150 is formed lining the surface of the substrate 102, to cover the shielding doped region 138, the source region 134, and the base region 136. In some embodiments, the gate dielectric layer 150 is formed on the substrate 102 by using a thermal oxidation process. In some embodiments, a thickness of the gate dielectric layer 150 is between 40 nm and 50 nm. In some embodiments, the gate dielectric layer 150 may be made of silicon dioxide or other oxides with high dielectric coefficients, and the gate dielectric layer 150 may also be made of a composite material.

A gate 160 is then formed in the first trench T1. The gate 160 may be formed in the following way: depositing a gate material layer on the gate dielectric layer 150, and completely filling the first trench T1. The gate material layer is then etched back to form the gate 160 in the first trench T1. An upper surface of the gate 160 may be lower than an upper surface of the gate material layer by 40-50 nm. In some embodiments, the gate 160 may be made of polysilicon, tantalum silicide, titanium silicide or tungsten silicide.

Then, a sacrificial oxide layer 170 may be formed on an upper surface of the gate 160 by using the thermal oxidation process. In some embodiments, a thickness of the sacrificial oxide layer 170 is between 40 nm and 50 nm. In some embodiments, an upper surface of the sacrificial oxide layer 170 is flush with an upper surface of the gate dielectric layer 150. The sacrificial oxide layer 170 may be used for repairing a surface of the gate 160 damaged when etching the gate 160, and therefore the surface of the gate 160 may become smoother.

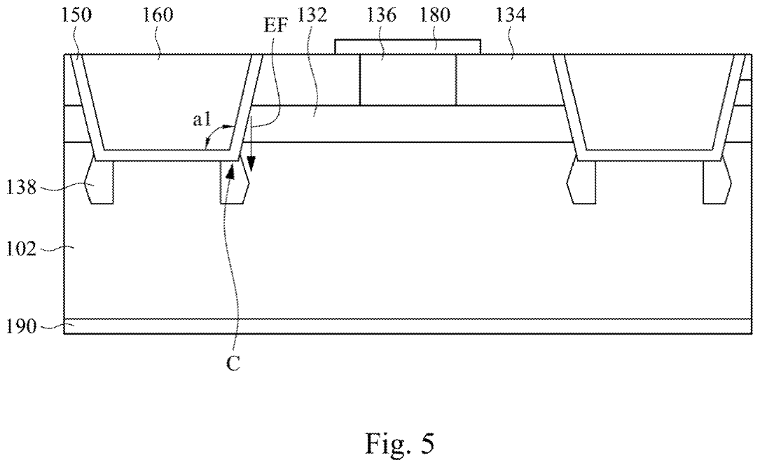

Referring to FIG. 5, a planarization process is performed to remove redundant gate dielectric layer 150 and the sacrificial oxide layer 170, to expose the source region 134, the base region 136, and the gate 160. Then a source contact 180 is formed on the base region 136, and a drain electrode 190 is formed below the substrate 102. Thus, the semiconductor device 100 can be obtained.

The semiconductor device 100 includes a substrate 102, a gate 160, a gate dielectric layer 150, a shielding doped region 138, a well region 132, a source region 134, and a base region 136. A gate 160 extends downward from a surface of the substrate 102, and a top width of the gate 160 is greater than a bottom width of the gate 160. The gate dielectric layer 150 is located between the substrate 102 and the gate 160. The shielding doped region 138 is located in the substrate 102 and below a corner C of the gate 160 and the gate dielectric layer 150. The well region 132 is located in the substrate 102 and on a side of the gate dielectric layer 150. The source region 134 is located in the substrate 102 and on a side of the gate dielectric layer 150, and the source region 134 is located on the well region 132. The base region 136 is located on the well region 132 and adjacent to the source region 134. The bottom of the well region 132 is higher than the shielding doped region 138, and the bottom of the well region 132 is higher than the bottom of the gate 160. The substrate 102 and the source region 134 have a first semiconductor type, the shielding doped region 138, the well region 132 and the base region 136 have a second semiconductor type, and the first semiconductor type is different from the second semiconductor type. The semiconductor device 100 may further include a source contact 180 and a drain electrode 190. The source contact 180 is on the base region 136, and the drain electrode 190 is below the substrate 102.

When a voltage is applied to the gate 160 and the source contact 180, a direction of an electron flow EF of the semiconductor device 100 is as shown in FIG. 5. Since the gate 160 of the semiconductor device 100 is trapezoidal, the shielding doped region 138 formed at the corner C of the gate 160 does not block the direction of the electron flow EF. In this way, the shielding doped region 138 can not only increase a breakdown voltage, but also alleviate the problem of gate leakage in the operation of the semiconductor device 100. The shielding doped region 138 does not block the direction of the electron flow EF, and thus the resistance of the semiconductor device 100 can also be reduced. In some embodiments, the gate 160 has an inclined side wall, the side wall of the gate 160 and the bottom of the gate 160 form an angle a1, and the angle a1 is in a range from 100 degrees to 130 degrees, for example, 113 degrees. When the angle a1 is in the disclosed range, the shielding doped region 138 is not easy to block the electron flow EF, and thus the resistance of the semiconductor device 100 can be reduced. When the angle a1 is less than the disclosed range, the shielding doped region 138 may block the electron flow EF, and thus the resistance of the semiconductor device 100 cannot be reduced. When the angle a1 is greater than the disclosed range, a spacing between the gate 160 and the gate 160 cannot be reduced, such that a quantity of gates 160 per unit area is also reduced.

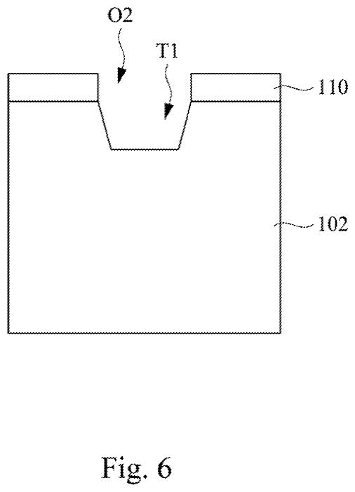

FIG. 6 illustrates a cross-sectional view of another embodiment of forming a first trench T1 according to the present disclosure.

A first etching process is performed on the hard mask layer 110 via the patterned photoresist layer, and an opening O2 is formed in the hard mask layer 110, and the opening O2 has a vertical side wall. During the first etching process, the etching parameters remain consistent. The etching parameters include etching gas concentration and etching energy, such that an etching gas in the etching process has the same etching capability for the hard mask layer 110 at different etching depths, thereby forming the opening O2 having a vertical side wall.

Then a second etching process is performed on the substrate 102 via the hard mask layer 110, to form a first trench T1 in the substrate 102. Performing a second etching process includes adjusting at least one of a plurality of etching parameters. The etching parameters include etching gas concentration and etching energy. For example, the plurality of etching parameters may be adjusted with a change in an etching depth of the substrate 102, such that an etching gas in the etching process has different etching capabilities for the substrate 102 at different etching depths, thereby forming the first trench T1. In some embodiments, when the substrate 102 is etched deeper, the etching gas concentration may be smaller or the etching energy may be smaller.

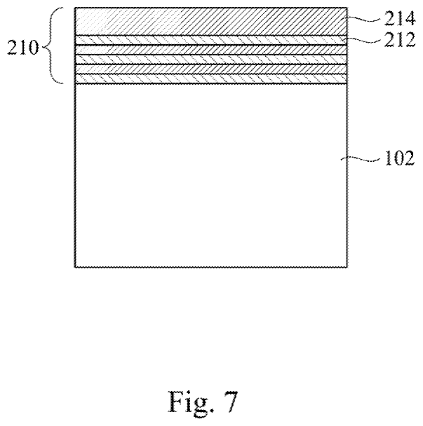

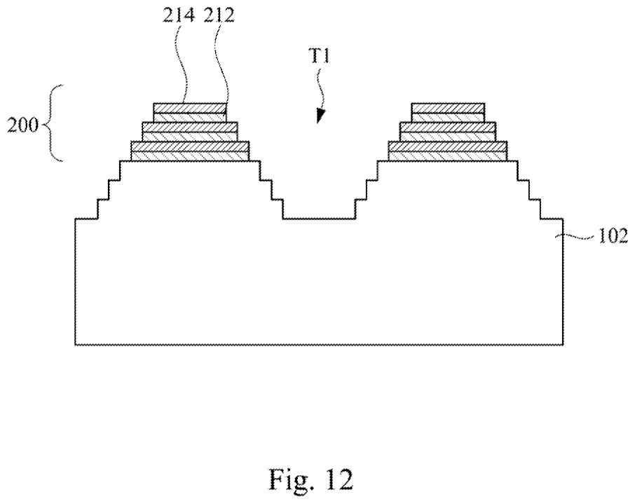

FIGS. 7-12 illustrate cross-sectional views of another embodiment of forming a first trench T1 according to the present disclosure. Specifically, in FIGS. 7-11, a stepped dielectric layer stack 200 is formed on the substrate 102, and then referring to FIG. 12, the substrate 102 is etched through the stepped dielectric layer stack 200, to form a first trench T1 in the substrate 102.

Referring to FIG. 7, a dielectric layer stack 210 is formed on the substrate 102, the dielectric layer stack 210 includes a plurality of first dielectric layers 212 and a plurality of second dielectric layers 214 stacked alternately, the plurality of first dielectric layers 212 are made of a third material, the plurality of second dielectric layers 214 are made of a fourth material different from the third material, and the third material and the fourth material have high etching selectivity therebetween. In some embodiments, the plurality of first dielectric layers 212 are made of silicon nitride, and the plurality of second dielectric layers 214 are made of polysilicon. The topmost layer of the second dielectric layer 214 of the dielectric layer stack 210 has a larger thickness than other second dielectric layers 214, and is 3-10 times the thickness of any of the other second dielectric layers 214. Moreover, in some embodiments, a thickness of each layer in the dielectric layer stack 210 is between 0.05 μm and 2 μm. In some embodiments, a total number of layers of the first dielectric layers 212 and the second dielectric layers 214 in the dielectric layer stack 210 is 6-10.

Then a photoresist layer is formed and patterned on the dielectric layer stack 210. In some embodiments, a total thickness of the photoresist layer is greater than 3 μm. In some embodiments, the total thickness of the photoresist layer is greater than a total thickness of the dielectric layer stack 210 by 1-3 μm. In some embodiments, the photoresist layer is formed by using a spin-coating process. Then the photoresist layer is exposed by using a photomask, and the photoresist layer is developed, to leave an unexposed region of the photoresist layer.

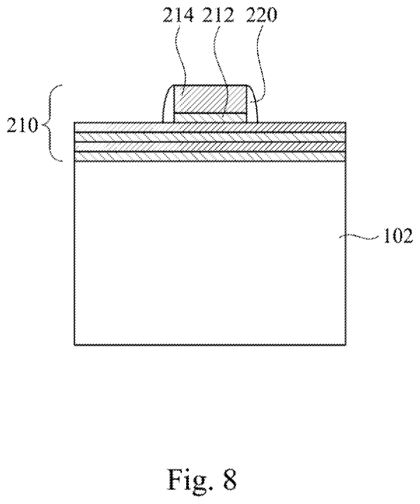

Referring to FIG. 8, the topmost layer of the second dielectric layer 214 and the topmost layer of the first dielectric layer 212 are patterned through the photoresist layer. Specifically, the topmost layer of the second dielectric layer 214 is first patterned through the photoresist layer, and then the topmost layer of the first dielectric layer 212 is patterned through the topmost layer of the second dielectric layer 214. Since the second dielectric layer 214 and the first dielectric layer 212 are made of different materials, when patterning the second dielectric layer 214, the first dielectric layer 212 may serve as an etch stop layer, and when patterning the first dielectric layer 212, the second dielectric layer 214 may serve as an etch stop layer.

Then, a first spacer 220 is formed on side walls of the topmost layer of the second dielectric layer 214 and the topmost layer of the first dielectric layer 212. The first spacer 220 may be formed in the following method: first forming a first spacer material layer lining a surface of the dielectric layer stack 210. The photoresist layer may be first removed before the first spacer material layer is formed. The first spacer material layer is made of a material different from materials of the first dielectric layer 212 and the second dielectric layer 214, and the material of the first spacer material layer and the materials of the first dielectric layer 212 and the second dielectric layer 214 have a high etching selectivity. In some embodiments, the first spacer material layer is made of silicon dioxide, and a thickness of the first spacer material layer is in a range from 0.5 μm to 2 μm.

Then the first spacer material layer of a horizontal portion is etched, and the first spacer material layer of a vertical portion is remained as the first spacer 220. In this way, a first spacer 220 is formed on side walls of the topmost layer of the second dielectric layer 214 and the topmost layer of the first dielectric layer 212. Since a material of the first spacer 220 is different from a material of the second dielectric layer 214, the second dielectric layer 214 may also serve as an etch stop layer when forming the first spacer 220, avoiding a surface of the dielectric layer stack 210 being damaged. A thickness of the first spacer 220 is the same as a thickness of the first spacer material layer.

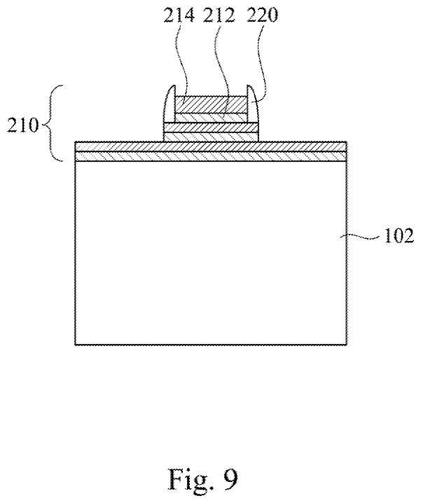

Referring to FIG. 9, the second layer of the second dielectric layer 214 and the second layer of the first dielectric layer 212 are patterned through the first spacer 220. Specifically, the second layer of the second dielectric layer 214 is first patterned through the first spacer 220, and then the second layer of the first dielectric layer 212 is patterned through the second layer of the second dielectric layer 214. Therefore, widths of the second layer of the second dielectric layer 214 and the second layer of the first dielectric layer 212 are greater than widths of the topmost layer of the second dielectric layer 214 and the topmost layer of the first dielectric layer 212. When the second layer of the second dielectric layer 214 is patterned through the first spacer 220, the topmost layer of the second dielectric layer 214 is also etched. However, the topmost layer of the second dielectric layer 214 has enough thickness, and thus may be not completely removed. The first spacer 220 may be removed after the second layer of the second dielectric layer 214 and the second layer of the first dielectric layer 212 are patterned.

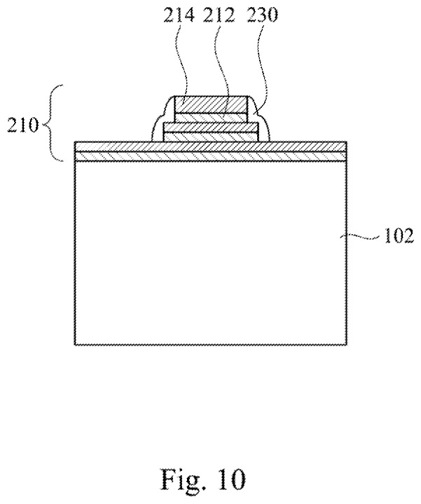

Referring to FIG. 10, a second spacer 230 is formed on side walls of the second layer of the second dielectric layer 214 and the second layer of the first dielectric layer 212. The second spacer 230 may be formed in the following method: forming a second spacer material layer lining a surface of the dielectric layer stack 210. The second spacer material layer of a horizontal portion is etched, and the second spacer material layer of a vertical portion is remained as the second spacer 230. The method of forming the second spacer 230 is the same as the method of forming the first spacer 220, and therefore related details are not described here.

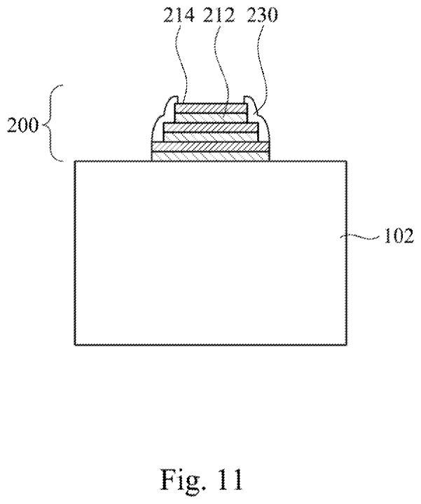

Referring to FIG. 11, a third layer of the second dielectric layer 214 and a third layer of the first dielectric layer 212 are patterned through the second spacer 230, to form a stepped dielectric layer stack 200. Specifically, the third layer of the second dielectric layer 214 is first patterned through the second spacer 230, and then the third layer of the first dielectric layer 212 is patterned through the third layer of the second dielectric layer 214. Therefore, widths of the third layer of the second dielectric layer 214 and the third layer of the first dielectric layer 212 are greater than widths of the second layer of the second dielectric layer 214 and the second layer of the first dielectric layer 212. When the third layer of the second dielectric layer 214 is patterned through the second spacer 230, the topmost layer of the second dielectric layer 214 is also etched. The second spacer 230 may be removed after the third layer of the second dielectric layer 214 and the third layer of the first dielectric layer 212 are patterned. In this way, the stepped dielectric layer stack 200 may be formed on the substrate 102.

When the stepped dielectric layer stack 200 is formed, the topmost layer of the second dielectric layer 214 is etched in specific steps. Therefore, when a thickness of the topmost layer of the second dielectric layer 214 is in the disclosed range, the topmost layer of the second dielectric layer 214 can be prevented from being completely removed during the process. If the thickness is less than the disclosed range, the topmost second dielectric layer may be completely removed during the process. If the thickness is greater than the disclosed range, it is not possible to form a stepped dielectric layer stack 200 of an expected shape. When the dielectric layer stack 210 includes more layers, the dielectric layer stack 210 may be patterned according to the ways described in FIGS. 7-12 of the present disclosure, to form a stepped dielectric layer stack 200 including more layers. When the patterned dielectric layer stack 210 is manufactured according to FIGS. 7-11, a plurality of dielectric layer stacks 210 may be formed on the substrate 102 at the same time.

Referring to FIG. 12, the substrate 102 is etched through two stepped dielectric layer stacks 200 spaced apart by a distance, to form a first trench T1 in the substrate 102. When the substrate 102 is etched, the etching parameters remain consistent. The etching parameters include etching gas concentration and etching energy. In this way, the etching gas naturally etches the first trench T1 in the substrate 102. In some embodiments, the first trench T1 has a stepped side wall like the side wall of the stepped dielectric layer stack 200.

In some embodiments, after the stepped dielectric layer stack 200 is removed, a sacrificial oxide layer may be formed on the substrate 102 by using the thermal oxidation process. The sacrificial oxide layer is then removed using a wet etching process. After the sacrificial oxide layer is removed, the process of the semiconductor device 100 may be completed with reference to the process in FIGS. 2-5. The completed semiconductor device 100 is similar to the semiconductor device 100 of FIG. 5, and the difference is that the gate 160 has a stepped side wall or an inclined side wall.

In conclusion, some embodiments of the present disclosure can be applied to form a gate that is wide at the top and narrow at the bottom. A gate trench that is wide at the top and narrow at the bottom may be formed in different ways. For example, the substrate is etched by using a hard mask layer having a conical opening to form a trapezoidal gate trench. The hard mask layer of the opening having a vertical side wall may be used, and when the substrate is etched, the etching parameters are changed to form a trapezoidal gate trench. The substrate may also be etched by using the stepped dielectric layer stack to form a trapezoidal gate trench. Therefore, the shielding doped region formed at a corner of the gate is not easy to block a path of an electron flow, thereby reducing the resistance of the semiconductor device.

What is claimed is:

1. A method of manufacturing a semiconductor device, comprising:
providing a substrate;
forming a first trench in the substrate, a top width of the first trench being greater than a bottom width of the first trench;
forming a well region and a source region at a side of the first trench, the source region being on the well region;
forming a hard mask stack lining a surface of the substrate;
forming a second trench in the hard mask stack, the bottom of the second trench being over a corner of the first trench;
performing an ion implantation process to form a shielding doped region at a region of the substrate nearing the corner of the first trench;
removing the hard mask stack;
forming a gate dielectric layer lining the surface of the substrate, the gate dielectric layer covering the shielding doped region; and
forming a gate in the first trench.

2. The method according to claim 1, wherein forming a first trench in the substrate comprises:
forming a hard mask layer on the substrate;
forming a patterned photoresist layer over the hard mask layer;
performing a first etching process on the hard mask layer via the patterned photoresist layer, to form an inverted trapezoidal opening in the hard mask layer; and
performing a second etching process on the substrate via the hard mask layer, to form the first trench in the substrate.

3. The method according to claim 2, wherein performing a first etching process comprises: adjusting at least one of a plurality of etching parameters of the first etching process, the etching parameters comprise etching gas concentration and etching energy, and during the second etching process, a plurality of etching parameters of the second etching process remain consistent.

4. The method according to claim 1, wherein the forming a first trench in the substrate comprises:
forming a hard mask layer on the substrate;
forming a patterned photoresist layer over the hard mask layer;
performing a first etching process on the hard mask layer via the patterned photoresist layer, to form an opening in the hard mask layer, wherein the opening has a vertical side wall; and
performing a second etching process on the substrate via the hard mask layer, to form the first trench in the substrate.

5. The method according to claim 4, wherein during the first etching process, a plurality of etching parameters of the first etching process remain consistent, the plurality of etching parameters comprise etching gas concentration and etching energy, and performing a second etching process comprises: adjusting at least one of a plurality of etching parameters of the second etching process.

6. The method according to claim 1, wherein forming a first trench in the substrate comprises:
forming two stepped dielectric layer stacks spaced apart by a distance on the substrate; and
etching the substrate through the two stepped dielectric layer stacks to form the first trench in the substrate.

7. The method according to claim 6, wherein forming two stepped dielectric layer stacks spaced apart by a distance on the substrate comprises:
forming a dielectric layer stack on the substrate, wherein the dielectric layer stack comprises a plurality of first dielectric layers and a plurality of second dielectric layers stacked alternately, the plurality of first dielectric layers are made of a first material, and the plurality of second dielectric layers are made of a second material different from the first material;
forming a photoresist layer on the dielectric layer stack, and patterning the photoresist layer;
patterning a topmost layer of the second dielectric layer and a topmost layer of the first dielectric layer through the photoresist layer;
forming a plurality of first spacers on a plurality of side walls of the topmost layer of the second dielectric layer and the topmost layer of the first dielectric layer;
patterning a second layer of the second dielectric layer and a second layer of the first dielectric layer via the plurality of first spacers;
removing the plurality of first spacers;
forming a plurality of second spacers on a plurality of side walls of the second layer of the second dielectric layer and the second layer of the first dielectric layer; and
patterning a third layer of the second dielectric layer and a third layer of the first dielectric layer via the plurality of second spacers, to form the two stepped dielectric layer stacks.

8. The method according to claim 7, wherein the topmost layer of the second dielectric layer of the dielectric layer stack has a larger thickness than any other second dielectric layers.

9. The method according to claim 1, further comprising:
forming a sacrificial oxide layer on the substrate after forming the first trench: and
removing the sacrificial oxide layer.

10. The method according to claim 1, wherein the hard mask stack comprises a first hard mask sublayer, a second hard mask sublayer and a third hard mask sublayer from bottom to top, the first hard mask sublayer and the third hard mask sublayer are made of a third material, and the second hard mask sublayer is made of a fourth material different from the third material.

11. The method according to claim 10, wherein a bottom of the second trench is on an upper surface of the first hard mask sublayer.

12. A semiconductor device, comprising:
a substrate;
a gate, extending downward from a surface of the substrate, a top width of the gate being greater than a bottom width of the gate;
a gate dielectric layer, located between the substrate and the gate;
a shielding doped region, located in the substrate and below a corner of the gate and the gate dielectric layer;
a well region, located in the substrate and on a side of the gate dielectric layer; and
a source region, located in the substrate and on the well region.

13. The semiconductor device according to claim 12, wherein a side wall of the gate and a bottom of the gate form an angle, and the angle is between 100 degrees and 130 degrees.

14. The semiconductor device according to claim 12, wherein a bottom of the well region is higher than a bottom of the gate.

15. The semiconductor device according to claim 12, further comprising a base region on the well region and adjacent to the source region.

16. The semiconductor device according to claim 12, wherein the substrate has a first semiconductor type, the shielding doped region has a second semiconductor type, and the first semiconductor type is different from the second semiconductor type.

17. A semiconductor device, comprising:
a substrate;
a gate, extending downward from a surface of the substrate, wherein the gate has a stepped side wall;
a gate dielectric layer, located between the substrate and the gate;
a shielding doped region, located in the substrate and below a corner of the gate and the gate dielectric layer;
a well region, located in the substrate and on a side of the gate dielectric layer; and
a source region, located in the substrate and on the well region.

18. The semiconductor device according to claim 17, wherein a top width of the gate is greater than a bottom width of the gate.

19. The semiconductor device according to claim 17, wherein a bottom of the well region is higher than the shielding doped region.

20. The semiconductor device according to claim 17, further comprising a base region on the well region and adjacent to the source region.
